(19) United States
(12) Patent Application Publication
(10) Pub. No.: US 2007/0079750 A1
(43) Pub. Date: Apr. 12, 2007

(54) Method of laser writing refractive index patterns in silicon photonic crystals

(76) Inventors: Herman Miguez, Valencia (ES); Geoffrey Alan Ozin, Toronto (CA); Nicolas Tetreault, Toronto (CA)

Correspondence Address: Ralph A. Dowell of DOWELL & DOWELL P.C., 2111 Eisenhower Ave, Suite 406, Alexandria, VA, 22314, US

(21) Appl. No.: 10/555,672

(22) PCT Filed: May 10, 2004
(86) PCT No.: PCT/CA04/00688

§ 371 Date: Dec. 4, 2006

Related U.S. Application Data
(60) Provisional application No. 60/468,957, filed on May 9, 2003.

(51) Int. Cl. C30B 7/00; C30B 21/02; C30B 28/06; C30B 9/00; C30B 11/00; C30B 17/00

(52) U.S. Cl. 117/68; 117/75

(57) ABSTRACT

The present invention discloses a method whereby laser microwriting is used to microanneal an amorphous silicon phase to a nanocrystalline silicon phase in silicon photonic crystals, films, fibers or surface patterns to enable the precise definition of a pre-determined refractive index contrast pattern in spatially designated regions of amorphous silicon photonic crystals, films, fibers or surface patterns in a rapid and straightforward fashion. At the micrometer length scale of the silicon photonic lattice the method can be used to create extrinsic defects in silicon photonic crystals, films, fibers or surface patterns, exemplified but not limited to points, lines and bends for localizing, guiding and bending light. It is also apparent that refractive index patterns can be laser written at larger length scales to create heterostructures in amorphous phase silicon photonic crystals, films, fibers or surface patterns, exemplified but not limited to junction, gradient, superlattice and modulated structures with designed photonic crystal properties and optical functionality. The laser microwriting-microanneling methodology described in this invention for creating spatially defined refractive index patterns in silicon photonic crystals may enable the future development of a range of silicon-based photonic crystal devices for all-optical chips, computers and telecommunication systems.

### CROSS REFERENCE TO RELATED U.S APPLICATION

This patent application relates to, and claims the priority benefit from, U.S. Provisional Patent Application Ser. No. 60/468,957 filed on May 9, 2003, which is incorporated herein by reference in its entirety.

### FIELD OF THE INVENTION

The present invention relates to a method of writing, with a laser, patterns of refractive index in photonic crystals in the form of crystals, films and fibers or colloidal photonic crystals patterned on a substrate that enables a way of making micrometer scale extrinsic defects exemplified by points, lines and bends as well as larger scale heterostructures exemplified by junctions, modulations, superlattices and gradients in the colloidal photonic crystals, films, fibers or patterned substrates. The method is exemplified using silicon photonic crystals that enable the development of a range of silicon-based photonic, crystal devices that for use in the assembly of all-optical chips, computers and telecommunication systems.

### BACKGROUND OF THE INVENTION

A colloidal photonic crystal (CPC) is a periodic dielectric lattice built of a regular array of microspheres (opals) or air holes (inverse opals). Microstructures of this type, in the form of crystals, films, fibers and surface patterns with a sufficiently high refractive index contrast, develop a large and full photonic bandgap (PBG) in their photon density of states (PDS) and have the unique ability to localize light, see Busch, K. & John, S. Photonic band gap formation in certain self-organizing systems; Physical Review E 58, 3896-3908 (1998).

The PBG creates a range of frequencies where electromagnetic waves are forbidden to propagate in the photonic lattice, an optical effect that may enable the experimental realization of new and improved performance optical components as disclosed in Joannopoulos, J. D., Villeneuve, P. R. & Fan, S. H. Photonic crystals: Putting a new twist on light, Nature 38 149 (1997).

The ability to spatially confine microspheres within geometrically defined surface relief patterns has enabled the planarization and miniaturization of CPC with simple and complex form and designed optical functionality. These are developments that may enable the utilization of CPC in a range of passive and active microphotonic devices Yang, S. M., Miguez, H. & Ozin, G. A., Opal circuits of light—Planarized microphotonic crystal chips, Advanced Functional Materials 12, 425-431 (2002).

To exploit the unique optical properties of CPC it is however necessary to be able to limit intrinsic defect density as these determine the quality of the optical and photonic crystal properties of CPC. However, to add particular functionalities, one needs to be able to introduce in a predetermined and predictable manner different kinds of extrinsic defects at distinct length scales into the photonic lattice, see Joannopoulos, J. D., Villeneuve, P. R. & Fan, S. H. Photonic crystals: Putting a new twist on light, Nature 386, 143-149 (1997).

At the length scale of the photonic lattice constant these defects include point or line vacancies envisioned to make micron scale lasers and waveguides. It is also important to be able to introduce defects at length scales substantially larger than the photonic lattice constant. These could be assembled into junction, gradient, modulated and superlattice photonic crystal architectures of different types whose optical band structures are designed to couple and switch light in specific regions of the photonic lattice.

The optical properties of laser annealed silicon film have been disclosed by Yu, G., Soga, T., Shao, C. L., Jimbo, T. & Umeno, M., Optical properties of excimer laser annealed polycrystalline Si by spectroscopic ellipsometry, Applied Surface Science 114, 489-492 (1997).

Laser micro-annealing of a-Si:H film and the subsequent study of crystal size and degree of crystallinity from Raman micro-spectroscopy has been disclosed in Viera, G., Huet, S. & Boufendi, L., Crystal size and temperature measurements in nanostructured silicon using Raman spectroscopy, Journal of Applied Physics 90, 4175-4183 (2001).

Before this work, the only report of laser defect engineering in a CPC at the micron length scale was by confocal optical microscope laser writing of a multi-photon polymerization reaction in an organic monomer imbibed within the CPC to create a line inside the photonic lattice as disclosed in Lee, W. M., Pruzinsky, S. A. & Braun, P. V., Multi-photon polymerization of waveguide structures within three-dimensional photonic crystals, Advanced Materials 14, 271−+(2002).

Therefore it would be very advantageous to provide a straightforward, rapid, robust and cost effective method that enables the introduction of extrinsic defects with different architectures and distinct length scales into colloidal photonic crystals, films, fibers and surface patterns, specifically but not limited to silicon colloidal photonic crystals with a complete photonic band gap at optical telecommunication wavelengths. Indeed it would be very beneficial if this same objective could be achieved for any structure of, for example, a silicon photonic crystal and in any form and therefore should not be limited to silicon colloidal photonic crystals as exemplified in the invention described herein.

### SUMMARY OF THE INVENTION

The present invention provides a new method to build patterns of refractive index contrast with arbitrary size and shape in any type of photonic crystals in any form exemplified in the invention described herein but not limited to silicon colloidal photonic crystals, films, fibers and surface patterns. By using a laser attached to a scanning optical microscope has enabled laser microwriting by microannealing an amorphous phase of a material so that a permanent phase change to form the nanocrystalline phase of the material is induced in a spatially well-defined region of the photonic lattice. This creates a local modification of the refractive index that can be usefully put into practice to introduce micron scale point, line and bend defects in a controlled manner in the photonic lattice as well as to build at a larger length scale different types of junction, gradient, superlattice and modulated heterostructures within the photonic lattice.

In a preferred embodiment of the invention laser microwriting is used to microanneal an amorphous silicon phase to a nanocrystalline silicon phase in silicon photonic crystals, films, fibers or surface patterns to enable the precise definition of a pre-determined refractive index contrast pattern in spatially designated regions of amorphous silicon photonic crystals, films, fibers or surface patterns in a rapid and straightforward fashion. At the micrometer length scale of the silicon photonic lattice the method can be used to create extrinsic defects in silicon photonic crystals, films, fibers or surface patterns, exemplified but not limited to points, lines and bends for localizing, guiding and bending light. It is also apparent that refractive index patterns can be laser written at larger length scales to create heterostructures in amorphous phase silicon photonic crystals, films, fibers or surface patterns, exemplified but not limited to junction, gradient, superlattice and modulated structures with designed photonic crystal properties and optical functionality. The laser microwriting-microanneling methodology described herein for creating spatially defined refractive index patterns in photonic crystals may enable the future development of a range of silicon-based photonic crystal devices for all-optical chips, computers and telecommunication systems.

In one aspect of the present invention there is provided a method of producing a pattern of refractive index contrast with arbitrary size and shape and structure in photonic crystals, comprising:

a) synthesizing a photonic crystal of a selected material;

b) directing an energy beam to a selected region of the photonic crystal for an effective period of time to induce a phase change in the structure of the selected region of the photonic crystal thereby changing a refractive index of the selected region; and

c) repeating step b) in pre-selected regions of the photonic crystal to produce the pattern of refractive index contrast in the photonic crystal.

In this aspect of the invention the selected material may be an organic (polymeric material) or an inorganic material. In this aspect of the invention the inorganic material may be silicon, and the photonic crystal may be an inverted silicon opal. In this aspect the energy beam may be a laser beam of effective wavelength and intensity to effect the phase change.

The present invention also provides a method of producing a pattern of refractive index contrast with arbitrary size and shape and structure in photonic crystals, comprising:

a) producing a silicon photonic crystal;

b) directing an energy beam to a selected region of the silicon photonic crystal for an effective period of time to induce a phase change in the structure of the selected region of the silicon photonic crystal thereby changing a refractive index of the selected region;

c) repeating step b) in pre-selected regions of the silicon photonic crystal to produce the pattern of refractive index contrast in the silicon photonic crystal; and

d) producing a silicon photonic crystal on top of the previously patterned photonic crystal.

In this aspect of the invention a hydrogen plasma may be used to selectively etch the refractive index pattern to produce air defects.

In another aspect of the invention there is provided a photonic crystal, comprising:

a) a photonic crystal of a selected material; and

b) a pattern of phase changes in the structure of selected regions of the photonic crystal thereby changing a refractive index of the selected regions to produce a pattern of refractive index contrast in the photonic crystal.

### BRIEF DESCRIPTION OF THE DRAWINGS

The methods of writing with a laser, micrometer size and larger scale extrinsic defects and heterostructures respectively, in amorphous phase silicon photonic crystals exemplified by, but not limited to, silicon colloidal photonic crystals, films, fibers or surface patterns according to the present invention will now be described, by way of example only, reference being made to the accompanying drawings, in which:

FIG. 1 shows a scanning electron micrograph (SEM) of a) the cleaved edge of a 9-layer thick rectangular a-Si:H iCPC microfibre made from φ=790 nm monodispersed silica spheres. The long-range order and low defect density can be observed. The crystalline orientation of the top surface is a (111), the side (112) and the cleaved edge (110); b) detail of the cleaved edge showing complete inversion; c) high magnification micrograph of the a-Si:H surface showing low surface roughness and good overall silicon infiltration. The scale bars represent a) 5 μm, b) 1 μm, and c) 0.5 μm.

FIG. 2 shows a schematic representation of the process of laser micro-annealing of a line defect in a a-Si:H iCPC. The writing direction of the laser is indicated by the solid arrow in a). Views of the laser writing process on the iCPC surface are presented in a), c) and e) while b), d), and f) show the respective cross-sections orthogonal to the laser beam and along the laser writing direction. The green circle represents the focal point of the laser beam on the top surface of the iCPC; a) focused Ar⁺ laser (radius R_{L}=0.55 μm) tracing a line on the a-Si:H iCPC's top surface; b) representation of the exposed volume where the 514 nm laser light is absorbed; c) detail of the exposed line pattern, the heat diffusion length (L) and the crystallization taking place at the solid/liquid interface (blue arrow) as it travels towards the center of the melted a-Si:H area; d) representation of the melted volume (depth ≈R_{L}+L); e) graphical illustration of the silicon nanocrystal size distribution in the micro-annealed line defect, where a larger nanocrystal volume fraction corresponds to a lower average refractive index.

FIG. 3: a) shows an optical micrograph of the top-surface of a silicon iCPC microfibre taken with a X100 objective. The sphere diameter is φ=790 nm. The long range order and overall quality of the silicon iCPC is observed. The laser micro-annealed line pattern of nc-Si:H is naturally yellow and easily distinguished from the darker orange/red a-Si:H microfibre. The pattern was written at 190 kW/cm² for 1 s. The transverse line of squares shows the positions where the Raman measurements shown in b) were taken. The scale bar represents 5 μm. b) Raman spectra of the iCPC microfibre. Grey lines correspond to the grey squares in a) while the black line corresponds to the black square. A Raman peak at 480 cm⁻¹ is indicative of a-Si:H, that at 517 cm⁻¹ of nc-Si:H. The FWHM of the nc-Si:H Raman peak was fitted using the correlation length model to a nanocrystal size of 2.7 nm. Deconvolution of the Raman spectra to obtain the crystalline volume fraction and subsequent fitting with the Bruggeman model revealed a refractive index of n=3.76 at the center of the microannealed pattern. c) High magnification SEM micrograph of the laser micro-annealed area. It can be observed that the structure is intact. The smoother and cleaner surface of the annealed region is attributable to the melting and solidification cycle. The scale bar represents 1 μm.

FIG. 4: a) shows a high magnification optical microscope image of the top-surface of a silicon iCPC microfibre. The sphere diameter is φ=790 nm. The laser micro-annealed pattern consists of a gradient of the refractive index made by cutting the microfibre at x=0 μm using a high laser power (>2000 kW/cm²) followed by a modulation of the refractive index along the microfibre and centered at x=17 μm and x=28 μm. The refractive index patterns were created by microannealing at 190 kW/cm² for 10 s. Study of the microfibre cross-section revealed that the a-Si:H, to nc-Si:H phase transition occurred throughout the thickness of the microfibre using these conditions. The line of square dots mark the Raman measurement positions every 1.5 μm along the main axis of the microfibre. The FWHM of the Raman peaks were fitted to the correlation length model b) The dotted line shows fitted values corresponding to a gradation of the nanocrystal size in nc-Si:H from 7 nm at the end of the microfibre decreasing steadily to 0 nm for a-Si:H, followed thereafter by a constant modulation of the nanocrystal size from around 3.0 nm to 0 nm (solid line) Fitted values of the refractive index showing a modulation from left to right from n=4.0 (a-Si:H) to about n=3.65 (nc-Si:H) before reaching n=3.45 at x=0 μm.

FIG. 5: a) Shows photonic band diagram for a face centered cubic arrangement of overlapping air spheres of diameter φ=860 nm covered by a shell of a mixture of amorphous (n=4.0) and nanocrystalline (n=3.45) silicon. The parameters used were Rair/φ=0.5035 for the air spheres and RSi/φ=0.577 for the silicon shell corresponding to a maximum experimental deposition by disilane CVD of 86% of the inverted volume. The refractive indices were fitted to the corresponding reflectivity spectra shown in b) taken before laser micro-annealing of a a-Si:H iCPC microfibre (solid line n=4.00) and after crystallization (dashed line n=3.85). The estimated degree of crystallinity is fc=0.27.

FIG. 6a shows spatially resolved Raman micro-spectroscopy diagnostic probe of the crystallization depth of a-Si:H to nc-Si:H phase change when an amorphous silicon colloidal photonic crystal is micro-annelaed with a laser with a laser power of 190 W/cm² and different exposure times. The solid curve represents the best fit through the experimental points.

FIG. 6b shows spatially resolved Raman micro-spectroscopy diagnostic probe of the crystallization depth of a-Si:H to nc-Si:H phase change when an amorphous silicon colloidal photonic crystal is micro-annelaed with a laser with a laser power of 230 W/cm² and different exposure times. The solid curve represents the best fit through the experimental points.

FIG. 7 shows a graphical representation of the strategy for focusing the writing laser beam either on the surface or within the silicon photonic crystal at a specific spatial location to write defect architectures, large and small within the photonic lattice. The left panel depicts the situation for short laser exposure times in a more strongly absorbing wavelength region (514 nm) of silicon yielding mainly surface defect writing in the silicon photonic lattice, the middle panel depicts the same region (514 nm) but for longer exposure times which extends the defect writing from the surface into the bulk of the silicon photonic lattice and the right panel depicts a less strongly absorbing wavelength region (900 nm) for a particular exposure time which enables the laser to be focused within the bulk of the silicon photonic lattice allowing defect writing at a particular location inside the bulk of the silicon photonic lattice.

FIG. 8 shows the wavelength dependence of the absorption coefficient of CVD thin silicon films made at different deposition temperatures and having different refractive indices.

FIG. 9 shows a general method for introducing a buried refractive index pattern defect or an “air” pattern defect. A colloidal photonic template is deposited onto a substrate before being infiltrated with silicon. An overlayer is grown as well. The laser is scanned over the top layer of the infiltrated photonic crystal to create the phase transition and, hence, the refractive index pattern. A colloidal photonic template is grown on top of the patterned silicon overlayer before being infiltrated with silicon. The colloidal photonic crystal is removed by wet chemical etching with HF. The refractive index pattern can also be selectively removed using hydrogen plasma to create an “air” pattern defect.

### DETAILED DESCRIPTION OF INVENTION

As used herein the term “phase change” is not intended to be restrictive and is intended to include interconversion between polymorphic crystalline forms of a material with the same composition or between crystalline and glassy forms of a material with the same composition or between crystalline and partially crystalline forms of a material with the same composition, where the term partially crystalline refers to a material comprised of a mixture of crystalline and glassy components and where the term mixture refers to either segregated or homogeneously integrated crystalline and glassy components and the term material refers to an inorganic or organic or composite of both.

Herein the inventors describe a new method that is designed to produce patterns of refractive Index contrast with arbitrary size and shape in photonic crystals exemplified but not limited to silicon inverted colloidal photonic crystals (iCPC) in the form of crystals, films, fibers and surface patterns. By using a laser attached to a scanning optical microscope one can perform laser microwriting by microannealing a hydrogenated amorphous silicon (a-Si:H) iCPC so that a permanent phase change to form the nanocrystalline silicon phase (nc-Si:H) is induced in a spatially well-defined region of the photonic lattice. This creates a local modification of the refractive index that can be put into practice to introduce micron scale defects in a controlled manner in the photonic lattice as well as to build at a larger length scale different types of junction, gradient, superlattice and modulated heterostructures within the photonic lattice. The controlled spatial modulation of the amorphous and crystalline phase and associated refractive indices of the silicon CPC and its effect on the resulting optical properties are demonstrated by Raman and near infrared micro-spectroscopy respectively and modeled with phonon confinement and optical band structure calculations.

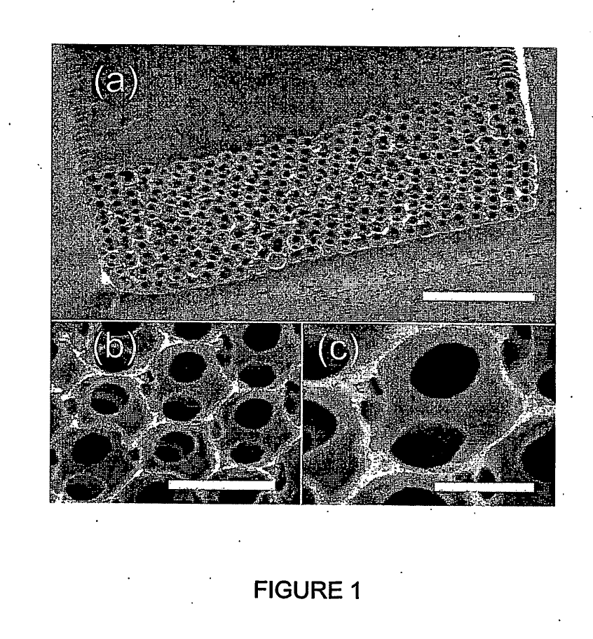

The laser micro-patterning was performed on oriented rectangular a-Si:H iCPC microfibres. Monodispersed silica microspheres were synthesized following a modified Stöber method (as disclosed in Stober, W., Fink, A. & Bohn, E. Controlled Growth of Monodisperse Silica Spheres in Micron Size Range. Journal of Colloid and Interface Science 26, 62-& (1968)) and re-grown to diameters of φ=790 nm and φ=860 nm. FIG. 1 shows a scanning electron micrograph (SEM) of a) the cleaved edge of a 9-layer thick rectangular a-Si:H iCPC microfibre made from φ=790 nm monodispersed silica spheres. The long-range order and low defect density can be observed. The crystalline orientation of the top surface is a (111), the side (112) and the cleaved edge (110); b) detail of the cleaved edge showing complete inversion; c) high magnification micrograph of the a-Si:H surface showing low surface roughness and good overall silicon infiltration. The scale bars represent a) 5 μm, b) 1 μm, and c) 0.5 μm.

The different diameter microspheres were then crystallized by assisted directed evaporation induced self-assembly (DEISA) of an ethanolic dispersion within the spatial confines of a parallel array of micrometer scale rectangular microchannels on a glass substrate, this method being described in U.S. patent application Ser. No. 09/977,254 which is incorporated herein in its entirety by reference. Convection and capillary forces cause the silica microspheres to nucleate and grow as well-ordered and oriented fcc colloidal crystals exclusively within the microchannels, with the top surface being a (111) crystalline plane, the walls (112) and the end surfaces (110). These silica colloidal crystals are then mechanically stabilized and connected with a continuous layer of SiO₂ from a room temperature acid catalyzed reaction of gas phase SiCl₄ (Aldrich 99%) with condensed water on the sphere surface using a method described in U.S. patent application Ser. No. 10/255,578 which is incorporated herein in its entirety by reference. The microfibres are subsequently infiltrated with silicon in a layer-by-layer fashion using either a home built static or dynamic chemical vapor deposition apparatus and disilane (Si₂H₆, Aldrich 99.99%) as the silicon precursor. For the static chemical vapor deposition (CVD) a disilane pressure of 100 Torr and a deposition temperature of 300° C. was used. In the case of the dynamic CVD a pressure of 2.4 Torr and a temperature of 395° C. was used.

To obtain free-standing oriented silicon iCPC microfibres all that is required is the sacrificial etching of the silica comprising the colloidal crystal template and the thin silica film on the surface of the silicon substrate using 1 wt.-% HF aqueous solution. This process results in the formation of a collection of free standing, rectangular silicon iCPC microfibres with a full PBG at 1.5 μm. These are then transferred to a glass substrate in preparation for laser micro-annealing. Laser writing of pre-defined refractive index patterns was done using a microscope fitted with a X100 objective (0.8 numerical aperture) and an argon ion laser (514 nm). Exposure time was varied between 0.5 and 10 s in a power density range of 190-2000 kW/cm².

The Raman probe studies were performed using the same setup but at lower power density (20 kW/cm²) with the microscope attached to a spectrometer and a silicon array charge coupled device (CCD) detector. This allows one to discriminate the Raman information coming from different parts of the microfibre with a precision of ≅1 μm² and therefore to study the variation of the amorphous and crystalline silicon regions and hence refractive index variations by mapping different spatial domains in the microfibre. The correlation length model, which quantifies the phonon confinement and thus allows the determination of the silicon crystallite size, is used to fit the peak width and its asymmetric line shape. A Bomem Fourier Transform Infrared spectrometer (FTIR) fitted with a microscope was subsequently utilized to investigate the optical reflectance spectra of the iCPC while the structural quality of the iCPC and its surface microtexture after irradiation were probed using a field emission scanning electron microscope (Hitashi S-4500).

In the following we amplify experimental details of the laser micro-annealing of silicon that enables spatially defined refractive index patterns to be written in a silicon iCPC having a full PBG. We use a focused Ar⁺ laser to perform spatially localized thermal micro-annealing of an iCPC made of hydrogenated amorphous silicon (a-Si:H). The annealing produces controlled patterns of hydrogenated nanocrystalline silicon (nc-Si:H) with a lower refractive index. This provides a convenient means of introducing extrinsic defects like points and lines as well as larger scale refractive index gradients and modulations for example. Local changes from a-Si:H to nc-Si:H within the iCPC are observed using Raman micro-spectroscopy, while Fourier transform infrared (FTIR) reflectance micro-spectroscopy documents changes in the optical properties of the iCPCs. High resolution scanning electron microscopy (SEM) is used to probe effects of laser microannealing on the integrity of the iCPC microstructure and microtextural alterations in the silicon.

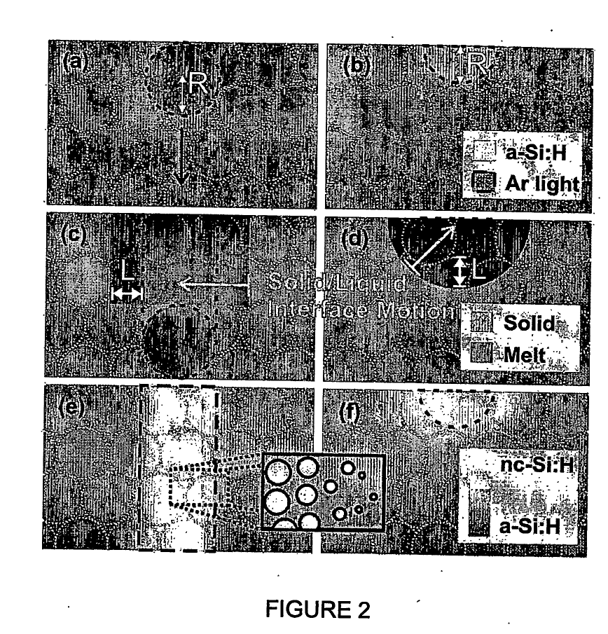

Localized microannealing was performed using the 514 nm wavelength line of a continuous Ar⁺ laser attached to a microscope fitted with a X100 magnification objective. FIG. 2 shows a schematic representation of the process of laser micro-annealing of a line defect in a a-Si:H iCPC. The writing direction of the laser is indicated by the solid arrow in a). Views of the laser writing process on the iCPC surface are presented in a), c) and e) while b), d), and f) show the respective cross-sections orthogonal to the laser beam and along the laser writing direction. The green circle represents the focal point of the laser beam on the top surface of the iCPC; a) focused Ar⁺ laser (radius R_{L}=0.55 μm) tracing a line on the a-Si:H iCPC's top surface; b) representation of the exposed volume where the 514 nm laser light is absorbed; c) detail of the exposed line pattern, the heat diffusion length (L) and the crystallization taking place at the solid/liquid interface (blue arrow) as it travels towards the center of the melted a-Si:H area; d) representation of the melted volume (depth≈R_{L}+L); e) graphical illustration of the silicon nanocrystal size distribution in the micro-annealed line defect, where a larger nanocrystal volume fraction corresponds to a lower average refractive index.

Selected areas of a-Si:H iCPC microfibres of about 1 μm² (radius of focused beam R_{L}=0.55 μm) were exposed for 4-10 seconds to produce nc-Si:H patterns in the a-Si:H phase. Shorter exposure times-(0.5-3 seconds) were used to create features with higher spatial resolution such as points or lines. The exposure time affects the heat diffusion length (L) and provides control over the spatial resolution of the pattern of annealing and its penetration into the iCPC lattice. A power density at the laser focal point in the range 190-230 kW/cm² and exposure between 0.5 s and 10 s is found to locally and briefly melt the rather poorly heat conducting a-Si:H phase. After exposure, crystallization of a-Si:H to nc-Si:H takes place in the liquid phase where solid/melt interface-controlled growth has been observed. Since the refractive index n of silicon can vary from n≈3.45 to n≈4.0 at λ=1.5 μm between the nc-Si:H and a-Si:H phase respectively, laser micro-annealing is expected to induce a modification of the refractive index at the micrometer length scale. Furthermore, a gradual variation of n between the aforementioned values can be achieved by tuning the nanocrystal volume fraction. FIGS. 2a, b, c, d, e and f illustrates how the dynamics of the laser micro-annealing process provides a means of writing refractive index patterns of nc-Si:H in an iCPC made of a-Si:H.

It will be appreciated by those skilled in the art that the method disclosed herein is not in any way limited to the method described above for making a photonic crystal of silicon. One can apply the present invention using a photonic crystal made in any way and of any material.

The present invention will now be exemplified and illustrated with the following non-limiting examples.

### EXAMPLE 1

Laser Microwriting of a Micrometer Scale Refractive Index Contrast Extrinsic Defect in a Silicon Colloidal Photonic Crystal

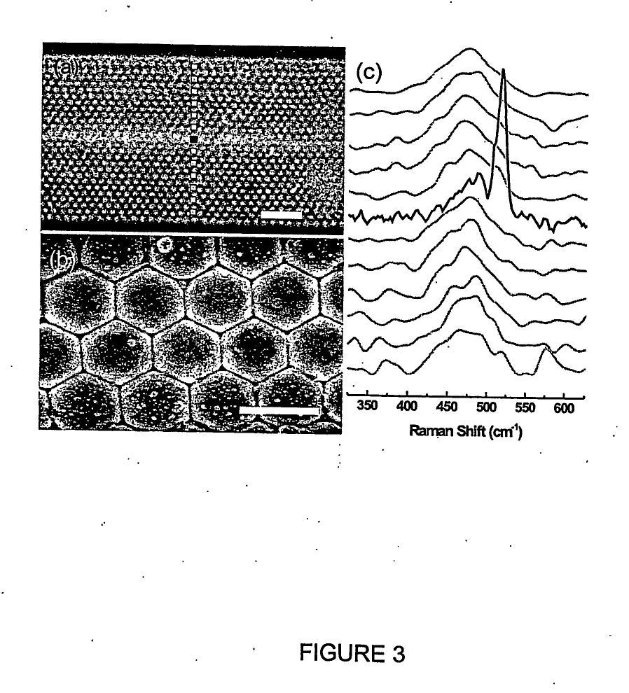

A spatially resolved refractive index pattern writing in a a-Si:H iCPC by laser micro-annealing is shown in FIG. 3(a). In this example, it can be observed that a line pattern about 1.3 μm wide has been written along the length of the a-Si:H microfibre. A laser power of 190 kW/cm² and an exposure time of 1 s were used for this example. The outcome of the refractive index patterning is seen in the optical microscope image as color changes from orange-red to yellow on passing from the unmodified part of the microfibre to the micro-annealed area. Because the dimensions of this defect line are too small to support optical Bragg diffraction, we believe the yellow color originates from the presence of the silicon nanocrystals and could be due to the variation of refractive index and electronic band gap. Additionally, a study of the microfibre cross-section showed that the penetration depth of the phase transition increases with exposure time. Using pulsed excimer lasers, Yu et al. (XeCl, λ=308 nm) and Angelis et al. (KrF, λ=248 nm, pulse duration=35 ns) found an increase of crystalline fraction and crystal size to f_{c}=0.913 and 145 nm respectively of nc-Si:H in an a-Si:H matrix with increasing power density up to a threshold of 280 mJ/cm². Further increase in power density is found to transform nc-Si:H back to a-Si:H. In our experiments the Ar⁺ laser (A=514 nm) exposure time was varied from 0.5 s to 10 s and power density from 190 to 2000 kW/cm². However, we found that nanocrystal size at the laser focal point was independent of exposure time but increased with the power density. Viera et al draw similar conclusions for laser annealing of a-Si:H on a planar substrate in the laser power range of 0.4 to 2000 kW/cm².

The micro-annealing effect on the silicon phase of the iCPC using the laser processing technique was monitored by Raman micro-spectroscopy. This was performed at 20 kW/cm² using a microscope attached to a Raman spectrophotometer and a silicon array charge coupled device (CCD) detector. This laser power is considered sufficiently small to avoid crystallization or thermal effects on the a-Si:H. The degree of crystallization of the amorphous silicon is assessed by monitoring the Raman signal corresponding to the crystalline silicon ┌′₂₅ phonon mode at 519 cm⁻¹ and the amorphous component mode at 480 cm⁻¹. In addition, the Raman peaks corresponding to nc-Si:H were fitted using a correlation length model to obtain a measure of the silicon nanocrystal size. This model, which quantifies phonon confinement and allows the determination of the crystallite size, is used to fit the Raman peak width and its asymmetric line shape. This way it proved possible to map the crystal size of nc-Si:H with a spatial resolution of about 1 μm² and at 1.5 μm intervals within the a-Si:H iCPC microfiber. The spatially resolved Raman measurements are summarized in FIG. 3(c). The Raman peak observed in the center of the line defect is shifted to 517 cm⁻¹ and displays a shoulder at 480 cm⁻¹. This clearly demonstrates the formation of nanocrystals in a matrix of a-Si:H. Using the correlation length model the nanocrystal size at the center of the line defect was estimated to be 2.7 nm. An SEM image of the laser-annealed surface shown in FIG. 3(b) clearly shows a smooth and intact surface.

### EXAMPLE 2

Laser Microwriting of a Buried Micrometer Scale Refractive Index Contrast Extrinsic Defect in a Silicon Colloidal Photonic Crystal

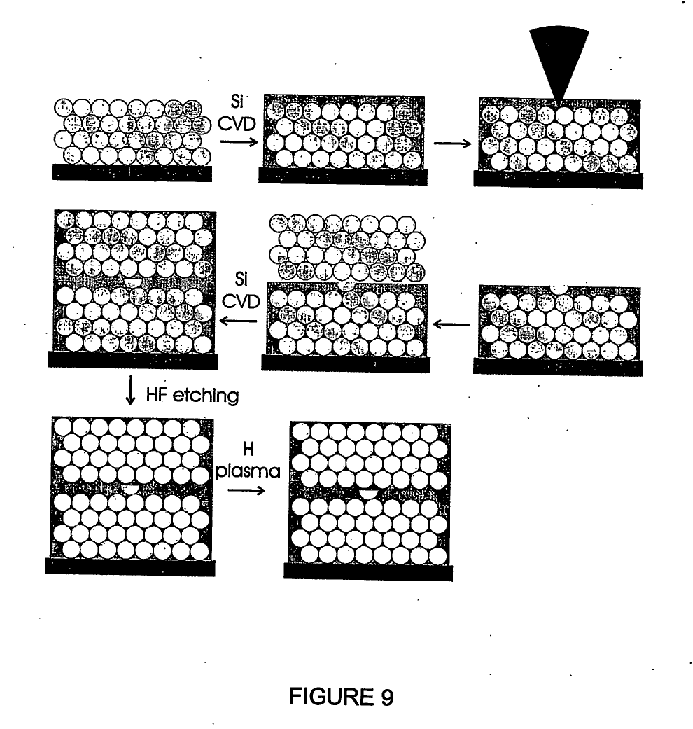

Another example of laser patterning of silicon iCPC microfibres is shown in FIG. 9 which shows a schematic of the synthesis process. The silica colloidal photonic template is grown onto a substrate and infiltrated with silicon. Note that the silicon can be over-deposited as to create a plannar silicon slab on top of the template is necessary. The laser writing procedure is then the same as in Example 1. A second silica colloidal photonic template is then grown over the refractive index pattern and infiltrated with silicon. The template is then chemically removed with HF aqueous solution. The refractive index pattern is thus buried between two slabs of Si iCPC.

The refractive index pattern can then be selectively removed by way of etching with hydrogen plasma to create an “air” pattern defect buried between two slabs of Si iCPC.

It is interesting and important to note in the context of this Example 2 that a theoretical blueprint of this kind of 3D-2D-3D photonic crystal heterostructure shows how to correctly lattice match the 2D silicon photonic crystal to the 3D silicon inverse opal PBG cladding layers, as described by Alongkam Chutinan, Sajeev John, Diffractionless Optical Networking in an Inverse Opal Photonic Band Gap Micro-chip, Journal of Photonics and Nanostructures (Elsevier) in press. If this can be reduced to practice, complete confinement of a large portion of the optical fiber telecommunication wavelength window within the 2D photonic crystal microcircuit will be possible. This would be a significant step towards a silicon based 3D PBG material optical networking solution.

### EXAMPLE 3

### Laser Microwriting of a Refractive Index Contrast Heterostructure in a Silicon Colloidal Photonic Crystal

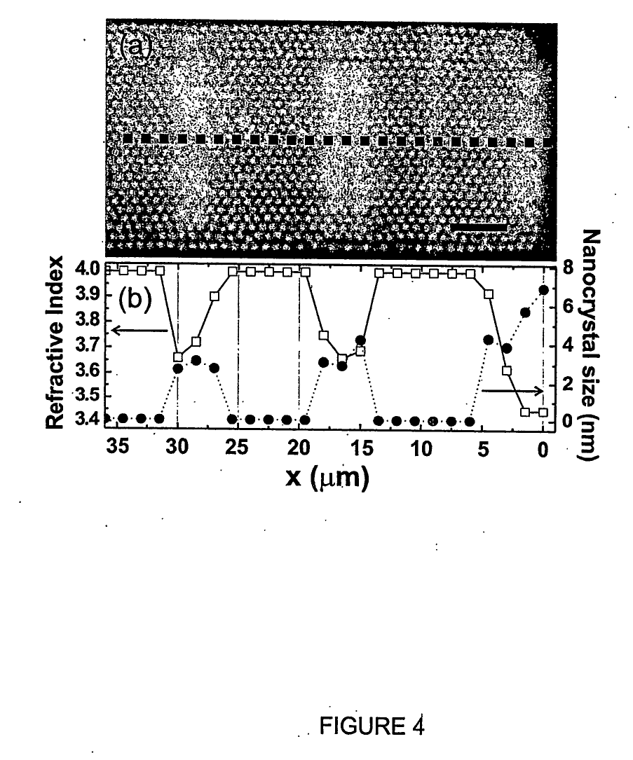

Another example of laser patterning of silicon iCPC microfibres is shown in FIG. 4(a) which shows a high magnification optical microscope image of the top-surface of a silicon iCPC microfibre in which the a-Si:H iCPC microfibre was cut perpendicular to the fibre axis with high laser radiation intensity (>2000 kW/cm²) which gives rise to a gradient of silicon nanocrystallite size and a corresponding gradient of low to high refractive index silicon. The sphere diameter is φ=790 nm. The laser micro-annealed pattern consists of a gradient of the refractive index made by cutting the microfibre at x=0 μm using a high laser power (>2000 kW/cm²) followed by a modulation of the refractive index along the microfibre and centered at x=17 μm and x=28 μm. The refractive index patterns were created by microannealing at 190 kW/cm² for 10 s to introduce a periodic modulation of the refractive index centered at x=17 μm and x=28 μm. The Raman spectrum of this modulated and graded microfibre was obtained every 1.5 μm along the fibre axis and fitted using the correlation length model to obtain the spatial variation of the nanocrystal size. Study of the microfibre cross-section revealed that the a-Si:H to nc-Si:H phase transition occurred throughout the thickness of the microfibre using these conditions. The line of square dots mark the Raman measurement positions every 1.5 μm along the main axis of the microfibre. The FWHM of the Raman peaks were fitted to the correlation length model.

FIG. 4(b) shows the variation of silicon nanocrystal size along the main axis of the microfibre. The dotted line shows fitted values corresponding to a gradation of the nanocrystal size in nc-Si:H from 7 nm at the end of the microfibre decreasing steadily to 0 nm for a-Si:H, followed thereafter by a constant modulation of the nanocrystal size from around 3.0 nm to 0 nm. The solid line shows fitted values of the refractive index showing a modulation from left to right from n=4.0 (a-Si:H) to about n=3.65 (nc-Si:H) before reaching n=3.45 at x=0 μm.

It is noted that the nanocrystal sizes obtained for the modulation pattern are fairly constant at about 3.0 nm while the nanocrystal size at the tip of the graded fibre is 7 nm. It is interesting to note that the steepness of the refractive index gradient can be adjusted by modifying the exposure time and hence the heat diffusion from the laser annealed area. The microfiber cross-section was also studied by spatially resolved Raman spectroscopy and established that the a-Si:H to nc-Si:H phase transition occurred throughout the thickness of the fiber (6.45 μm).

The inventors have used two strategies for obtaining an estimate of the degree of crystallinity and change of refractive index of a a-Si:H microfibre that has been laser microannealed. To amplify, the first method involves derivation of the crystalline volume fraction (f_{c}) from the integrated scattering intensities of the amorphous (lₐ) and crystalline (l_{c}) components of the transverse optical mode of the Raman spectra:

$${f}_{c} = \frac{{I}_{c}}{{I}_{c} + γ {I}_{a}}$$

$$γ = 0.1 + {ⅇ}^{- ( \frac{D}{250} )}$$

where γ is the ratio between the integrated Raman cross-sections of the crystalline and the amorphous phases and D is the nanocrystal size (Å) obtained from the correlation length model described previously. Using the Bruggeman effective medium approximation, one can then estimate the refractive index in the annealed region of our a-Si:H iCPC microfibre by assuming a physical mixture of crystalline silicon (c-Si, ε_{c}=11.9) in a matrix of amorphous silicon (a-Si, εₐ=16.0 and fₐ=1−f_{c});

$${f}_{a} \frac{{ɛ}_{a} - ɛ}{{ɛ}_{a} + 2 ɛ} + {f}_{c} \frac{{ɛ}_{c} - ɛ}{{ɛ}_{c} + 2 ɛ} = 0$$

where ε is the dielectric constant of the composite. Using these relations, we obtained a refractive index of n=3.76 and crystalline volume fraction of f_{c}=0.44 at the center of the laser micro-annealed pattern presented in FIG. 3. Furthermore, the calculated refractive index values for the modulated and gradient microfibre patterns are represented by the solid line in FIG. 4(b).

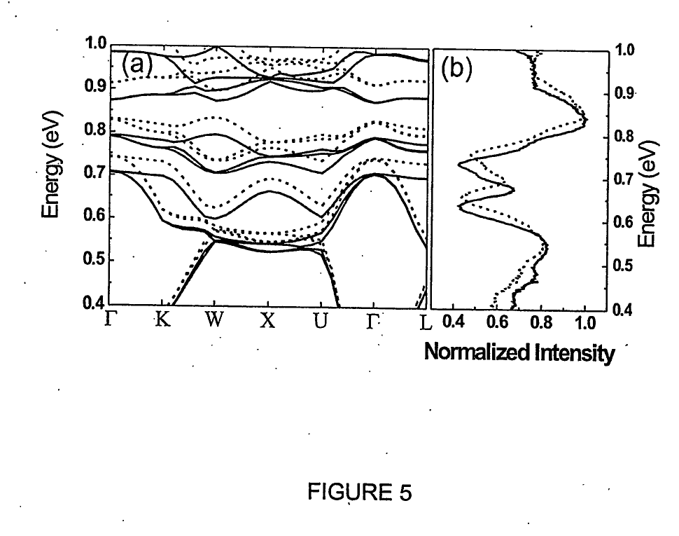

The second strategy involved fitting the optical reflectance spectra to photonic band structure calculations. To do so, we measured the variation in the optical reflectivity of a region of 20 μm (total width)×50 μm (length) of a a-Si:H iCPC microfibre before and after microannealing at 230 kW/cm² with 1 s exposure time. A clear blue shift is observed for all optical stop bands after microannealing and is in good agreement with the expected decrease of the refractive index due to crystallization. Theoretical fitting revealed a lowering of the refractive index by 3.75% from n=4.00 to n=3.85, which is still far from the reported maximum achievable nanocrystal volume fraction of f_{c}=0.913 at n=3.5. The reflectance spectra are plotted in FIG. 5b together with their respective optical band diagram in FIG. 5a. Using the Bruggeman effective medium approximation we could estimate the crystalline volume fraction to be f_{c}=0.27 after laser microannealing.

More particularly FIG. 5a) shows the photonic band diagram for a face centered cubic arrangement of overlapping air spheres of diameter φ=860 nm covered by a shell of a mixture of amorphous (n=4.0) and nanocrystalline (n=3.45) silicon. The parameters used were Rair/φ=0.5035 for the air spheres and RSi/φ=0.577 for the silicon shell corresponding to a maximum experimental deposition by disilane CVD of 86% of the inverted volume. The refractive indices were fitted to the corresponding reflectivity spectra shown in FIG. 5b) taken before laser micro-annealing of a a-Si:H iCPC microfibre (solid line n=4.00) and after crystallization (dashed line n=3.85). The estimated degree of crystallinity is f_{c}=0.27.

The consistency between the calculated degree of crystallinity and refractive indices obtained by fitting both Raman and optical data to theoretical models, for different samples and synthesis conditions, provides credence for the method of writing refractive index patterns with lasers in Si iCPCs. We also believe that it should be possible to laser write patterns with a higher degree of crystallinity corresponding to lower refractive indices in any a-Si:H based photonic crystal lattice and morphology. Additionally, pulsed lasers at shorter wavelengths could improve control over energy density, spatial and depth resolution. We believe these same principles can be applied with little modifications to laser writing refractive index patterns within photonic crystals to achieve specific optical functionality.

The above results have involved laser irradiation of selected positions in a-Si:H to cause a local phase change to nc-Si:H. However, it will be appreciated that by selecting the laser power levels and wavelengths carefully, it is possible to perform the laser microwriting microannealing in silicon to cause the amorphous-nanocrystalline silicon phase change to occur in either direction, namely from the a-Si:H to nc-Si:H as exemplified above and also from the nc-Si:H form to the a-Si:H form thereby going from a high refractive index phase of silicon (nc-Si:H) to the lower refractive index phase (a-Si:H). The defects written with the laser in the silicon photonic crystal depends on whether one begins with the amorphous or nanocrystalline silicon photonic crystal. Hence one can either have a lower or higher refractive index relative to the non-laser written regions depending whether one begins with an a-Si:H or nc-Si:H silicon photonic crystal to write nc-Si:H or a-Si:H, respectively.

### EXAMPLE 4

### Dependence of Laser Writing Phase Change Depth in a Silicon Colloidal Photonic Crystal on Laser Power and Laser Exposure Time

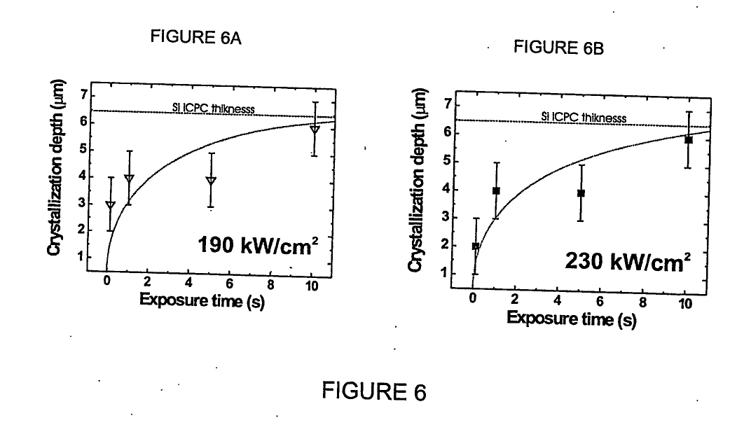

To probe how the laser diagnostics affect phase change depth into the silicon colloidal photonic crystal, spatially resolved Raman micro-spectroscopy was employed to probe the depth profile of the a-Si:H to nc-Si:H phase transition through the entire cross-section of the laser micro-annealed sample. In this investigation two laser powers (190, 230 kW/cm²) and a range of exposure time (0.5-10 s) were employed to effect the phase change. As presented in graphical form in FIGS. 6a and 6b it was found that the phase transition depth into the silicon colloidal photonic crystal was essentially independent of power and increased with exposure time. After 10 s exposure the entire thickness of the a-Si:H sample irradiated area had transformed to nc-Si:H. These results provide clearly show the outcome of the laser micro-annealing of a silicon colloidal photonic crystal.

It will be understood that by performing the laser writing and laser annealing in a wavelength region close to the absorption edge of silicon, say 800-1100 nm in the near IR, there is less absorption of the laser light at the surface and therefore greater depth penetration into the silicon photonic crystal. This makes it possible to focus the laser and therefore concentrate the energy of the microannealing process at specific spatial regions “within” the silicon photonic crystal beneath the surface. In this way it is possible to laser write the defects at any point “inside” the silicon photonic crystal. Thus, it will be appreciated by those skilled in the art that while the present invention has been exemplified using visible laser wavelengths around 514 nm where the silicon absorbs very strongly, (which means the laser penetration and focus is more concentrated in the surface regions and the laser microannealing follows more the thermal profile induced by the laser from the surface and within the silicon photonic crystal in the irradiate region) this invention is by no means limited to inducing refractive index changes at the surface of the crystal.

By tuning the wavelength, defects can be written at selected depths in the crystal. By illuminating the crystal with laser wavelengths that are strongly absorbed near the surface produces laser induced refractive index changes whose penetration depth into the silicon photonic crystal depend on laser intensity and laser duration at a particular spatial region. In this way one is not able to place the defect exclusively inside the silicon photonic crystal at a specific location, instead it extends from the silicon photonic crystal surface into the crystal to a depth that depends on laser fluence and irradiation time at a specific spot on the crystal. The salient issue is that by selecting the laser irradiation wavelength, intensity, and time of irradiation it is possible to precisely control the location and architecture of the defect inside and/or on the surface of the silicon photonic crystal. Clearly for practical applications it is desirable to place the defects inside the silicon photonic crystal. However the other architectures we describe, like junctions, gradients, modulations and so forth in the silicon photonic crystal are also important.

The present invention provides a method of producing refractive index profiles in photonic crystals using spatially resolved laser micro-annealing to induce localized phase transitions inside the bulk of the crystal or on the surface depending on the wavelength and intensity of the laser light. The invention has been exemplified using silicon photonic bandgap materials in which a phase change has been induced in either direction, from a-Si:H to nc-Si:H or nc-Si:H to a-Si:H.

This method enables the creation of micrometer size extrinsic defects or larger structures like junctions, gradients, or superlattices in silicon based photonic crystals. Patterning variations of the refractive index provides a simple means of tailoring the optical properties of silicon photonic crystals and purposefully designing optical functionality and means of coupling light into high refractive index contrast 3-D photonic microstructures that display omnidirectional PBGs. This work bodes well for the future development of a range of silicon photonic crystal miniaturized optical components, devices and circuits.

Wavelengths of the laser used to illuminate the selected regions of the photonic crystal may include those in the UV obtained with an excimer KrF laser, λ=248 nm as a good example all the way to the absorption tail of a-Si:H (when a silicon photonic crystal is used) which would be at about 950 nm. Further, in the case of silicon, any wavelength may be used that is absorbed effectively by the silicon and that would provoke the necessary local heating above its melting point. The present process may be carried out using either pulsed or continuous lasers. The laser system for illuminating the selected regions may also be a confocal laser system configured for two-photon absorption in this wavelength range as well.

With respect to intensities of the illuminating laser beam, for pulsed excimer laser the crystallization (a-Si:H to nc-Si:H) threshold is at 150-160 mJ/cm² and the crystallization process extends all the way to about 270-280 mJ/cm². Amorphization (nc-Si:H to a-Si:H) happens for any intensity above that. Any pulse range from femtoseconds to seconds for continuous lasers may be used to Induce the nc-Si:H to a-Si:H change. For continuous YAG lasers with wavelengths higher than 500 nm the intensity range may be in the range extending from about 100 kW/cm² to well in excess of 2,000 kW/cm².

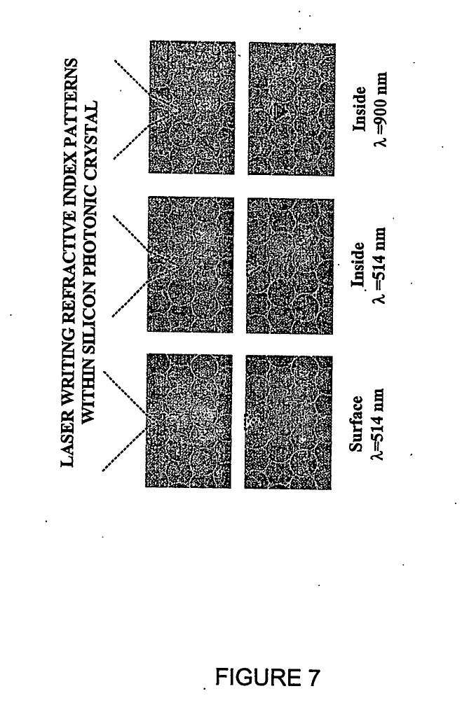

FIG. 7 shows a graphical representation of the strategy for focusing the writing laser beam on the surface or within the silicon photonic crystal at a specific spatial location to write defect architectures, large and small within the photonic lattice. The left panel depicts the situation for short laser exposure times in a more strongly absorbing wavelength region (514 nm) of silicon yielding mainly surface defect writing in the silicon photonic lattice, the middle panel depicts the same region (514 nm) but for longer exposure times which extends the defect writing from the surface into the bulk of the silicon photonic lattice and the right panel depicts a less strongly absorbing wavelength region (900 nm) for a particular exposure time which enables the laser to be focused within the bulk of the silicon photonic lattice allowing defect writing at a particular location inside the bulk of the silicon photonic lattice.

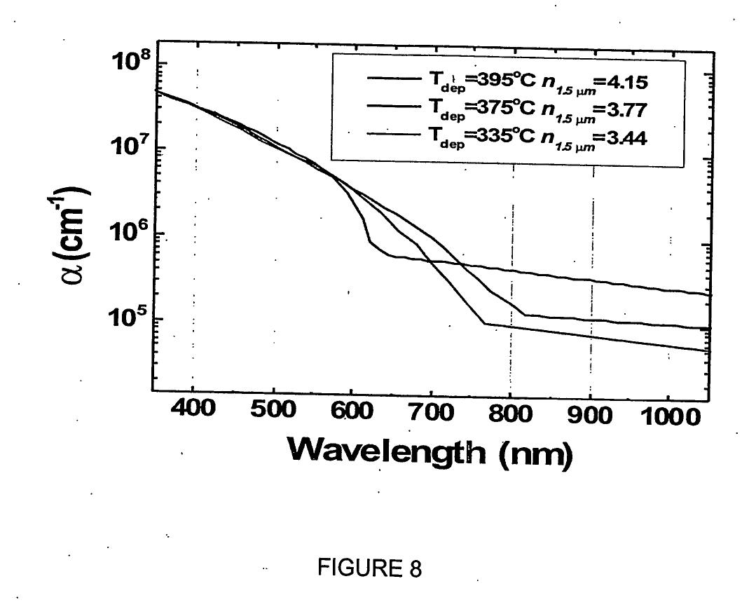

Thus by adjusting the laser wavelength with respect to the absorbing and non absorbing spectral regions of amorphous or nanocrystalline silicon one can control the laser penetration depth into the amorphous or nanocrystalline silicon photonic crystal lattice and hence the ability to write predetermined phase changes of say a-Si:H to nc-Si:H or nc-Si:H to a-Si:H at specific positions and depths within the photonic lattice. Thus, wavelength dependence of laser penetration depth of focus in a silicon photonic crystal provides control over position and depth of laser micro-annealed refractive index phase changes as illustrated in FIG. 7. FIG. 8 shows the wavelength dependence of the absorption coefficient of CVD thin silicon films made at different deposition temperatures and having different refractive indices from which it can be seen that laser micro-annealing with longer wavelength pulsed laser (800-1000 nm) decreases absorption and hence the phase transition at the laser focus can be induced and localized within the bulk rather than the surface regions of the silicon photonic lattice. With respect to the step of hydrogenation, although the [H] content varies greatly and is dependent on the deposition technique, the substrate temperature, H₂ dilution of the hydride gas, etc. the concentration [H] may vary from 0% for completely amorphous and high refractive index (n=4.1-4.2) a-Si:H to 30 atomic % for ultra low refractive index a-Si:H (n=2.3-2.4). The hydrogen content will adjust itself with the modification of the refractive index during crystallization.

Studies by the inventors of the refractive indexes obtained show that a high refractive index of about 4.2 for a-Si:H has been obtained and a low refractive index of about 3.45 for laser annealed nc-Si:H has been achieved. The photonic crystals may be subjected to pre- or post-treatment that may include furnace annealing under H₂ to completely crystallize the as deposited a-Si:H to form nc-Si:H/poly-Si:H before laser annealing over the amorphization laser power threshold to create a high refractive index defect/heterostructure.

The newly laser annealed nc-Si:H may be subjected to oxygen plasma treatment and/or furnace annealing under H₂ to reduce the defect density at the grain boundaries of the newly laser annealed nc-Si:H in order to reduce its absorption or refractive index further, improve and/or manipulate its electric or photonic properties. Further, it may be preferable to induce selective reaction on the nc-Si:H or a-Si:H part of the PBG material that would further manipulate the photonic properties of the defect or the PBG in general by increasing/decreasing its refractive index, increasing/decreasing its absorption, modify its electronic properties or add/remove material.

The as depositied a-Si:H may be furnace annealed under hydrogen to crystallize the high refractive index a-Si:H PBG to form low refractive index nc-Si:H PBG. Patterns of a-Si:H are then written on the surface or in the bulk of the PBG crystal by laser annealing over the amorphization laser power threshold. The pattern is then selectively etched by a hydrogen (H) plasma, to form an “air” pattern on the surface or in the bulk of the PBG crystal. In this invention while the phase change between amorphous and crystalline forms of silicon have been exemplified by laser micro-annealing using a photon beam, it is to be understood that other energy beams may be used to effect these phase changes such as electron, ion and atomic beams. In this invention the use of the term “phase change” is not intended to be restrictive and is intended to include interconversion between polymorphic crystalline forms of a material with the same composition or between crystalline and glassy forms of a material with the same composition or between crystalline and partially crystalline forms of a material with the same composition, where the term partially crystalline refers to a material comprised of a mixture of crystalline and glassy components and where the term mixture refers to either segregated or homogeneously integrated crystalline and glassy components and the term material refers to an inorganic or organic or composite of both.

While the present invention disclosing a method for laser writing refractive index patterns in photonic crystals has been exemplified using silicon, it will be appreciated that this method is readily applicable to photonic crystals comprised of materials other than silicon. The method is contemplated by the inventors to be useful for laser writing patterns in photonic crystals produced from inorganic materials that undergo a phase change including silicon, germanium, selenium, tellurium, tellurium binary and ternary alloys, zinc and cadmium chalcogenides, arsenic and antimony chalcogenides, germanium chalcogenides, tin chalcogenides, lead chalcogenides. For example, photonic crystals such as but not limited to GeS₂, GeSe₂, Sb₂S₃, PbS and PbSe are contemplated by the inventors to be able to be patterned with refractive index patterns similar to silicon photonic crystals. The method is contemplated by the inventors to also be useful for laser writing refractive index patterns in photonic crystals produced from organic materials that undergo a phase change.

As used herein, the terms “comprises”, “comprising”, “including” and “includes” are to be construed as being inclusive and open ended, and not exclusive. Specifically, when used in this specification including claims, the terms “comprises”, “comprising”, “including” and “includes” and variations thereof mean the specified features, steps or components are included. These terms are not to be interpreted to exclude the presence of other features, steps or components.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

1. A method of producing a pattern of refractive index contrast with arbitrary size and shape and structure in photonic crystals, comprising:
a) synthesizing a photonic crystal of a selected material;
b) directing an energy beam to a selected region of the photonic crystal for an effective period of time to induce a phase change in the structure of the selected region of the photonic crystal thereby changing a refractive index of the selected region; and
c) repeating step b) in pre-selected regions of the photonic crystal to produce the pattern of refractive index contrast in the photonic crystal.

2. The method according to claim 1 wherein the energy beam is a laser beam of effective wavelength and intensity to effect the phase change.

3. The method according to claim 1 wherein the selected material is an inorganic material.

4. The method according to claim 3 wherein the inorganic material is selected from the group consisting of silicon, germanium, selenium, tellurium, tellurium binary and ternary alloys, zinc and cadmium chalcogenides, arsenic and antimony chalcogenides, germanium chalcogenides, tin chalcogenides and lead chalcogenides.

5. The method according to claim 3 wherein the selected inorganic material is silicon so that the photonic crystal is a silicon photonic crystal.

6. The method according to claim 5 wherein step of synthesizing a photonic crystal includes the steps of:
crystallizing monodispersed silica microspheres with a pre-selected diameter on a substrate to form a colloidal crystal;
stabilizing the colloidal crystal;
infiltrating the colloidal crystal with a silicon containing fluid and depositing silicon on the silica microspheres of the colloidal crystal; and
selectively etching away the silica microspheres to yield a silicon inverted colloidal photonic crystal.

7. The method according to claim 5 including hydrogenating the photonic crystal to incorporate hydrogen into the photonic crystal prior to performing steps b) and c).

8. The method according to claim 7 wherein the hydrogenated photonic crystal is hydrogenated amorphous silicon photonic crystal (a-Si:H), and wherein illuminating selected regions of the a-Si:H causes a local phase change to nanocrystalline hydrogenated silicon (nc-Si:H).

9. The method according to claim 7 wherein the hydrogenated photonic crystal is hydrogenated nanocrystalline silicon photonic crystal (nc-Si:H), and wherein illuminating selected regions of the nc-Si:H causes a local phase change to hydrogenated amorphous silicon (a-Si:H).

10. The method according to claim 7 wherein a concentration of hydrogen [H] used for the step of hydrogenating the silicon photonic crystal is in a range of 0<[H]≦30 at %.

11. The method according to claim 7 wherein the hydrogenated photonic crystal is hydrogenated amorphous silicon photonic crystal (a-Si:H), including annealing the a-Si:H under H₂ to substantially completely crystallize the as-deposited a-Si:H to form nc-Si:H/poly-Si:H prior to step b), and wherein step b) includes illuminating selected regions of the photonic crystal with a laser beam having an effective laser power which induces amorphization in said selected regions to create a high refractive index defect/heterostructure.

12. The method according to claim 8 wherein the as produced amorphous a-Si:H has a high refractive index of about 4.2, and wherein after the pattern of refractive index contrast has been produced in the silicon photonic crystal, the nc-Si:H portions of the silicon photonic crystal produced by irradiation by the laser beam has a low refractive index of about 3.45.

13. The method according to claim 8 wherein the concentration of hydrogen [H] in the silicon photonic crystal is in a range from about 0% for substantially completely amorphous a-Si:H silicon photonic crystal and high refractive index in a range from about n=4.1 to 4.2 to a concentration of hydrogen [H] of about 30 at % for ultra low refractive index a-Si:H having a refractive index of about n=2.3 to 2.4.

14. The method according to claim 1 wherein the photonic crystal is a three dimensional photonic crystal, a two dimensional photonic crystal film, a one dimensional photonic crystal fiber or patterned versions of these photonic crystal morphologies.

15. The method according to claim 1 wherein step a) of producing a photonic crystal of a selected inorganic material includes growing an overlayer of a selected material onto a top surface of the photonic crystal to provide a planar surface, and wherein after step c) including producing a second photonic crystal of a selected inorganic material includes on a top surface of the overlayer.

16. The method according to claim 7 wherein the photonic crystal is a hydrogenated amorphous silicon photonic crystal (a-Si:H), and wherein the laser beam induces a spatially well-defined change of the amorphous phase to a crystalline phase of silicon which results in an associated spatially well-defined refractive index change of the silicon photonic crystal.

17. The method according to claim 7 wherein adjusting the wavelength of the laser beam, fluence of the laser beam, continuous or pulsed laser operation mode and laser dwell time provides control of the nature of the silicon phase comprising the refractive index contrast pattern written in the amorphous phase silicon by varying the extent of conversion of the amorphous phase silicon to form the nanocrystalline phase silicon and thereby controlling the refractive index of the laser micro-processed silicon between about 4 for a substantially pure amorphous phase to about 3.4 for a substantially pure crystalline phase.

18. The method according to claim 8 wherein after the step of illuminating the selected regions of the a-Si:H causes a local phase change to nanocrystalline hydrogenated silicon (nc-Si:H), including subjecting the silicon photonic crystal to an oxygen plasma treatment to reduce defect density at grain boundaries of the newly laser annealed nc-Si:H in order to reduce its refractive index further, improve and/or manipulate its electric or photonic properties.

19. The method according to claim 1 wherein step of synthesizing a photonic crystal includes synthesizing an inverted silicon colloidal photonic crystal from monodispersed silica microspheres synthesized with diameters in a range from about 0.1 to 3 about microns.

20. The method according to claim 7 wherein an Ar⁺ laser is used to perform spatially localized thermal micro-annealing of the photonic crystal made of hydrogenated amorphous silicon (a-Si:H) to produce controlled patterns of hydrogenated nanocrystalline silicon (nc-Si:H) with a lower refractive index.

21. The method according to claim 7 wherein the step a) of producing a photonic crystal of a selected material includes producing a hydrogenated amorphous silicon photonic crystal (a-Si:H), including annealing the a-Si:H in the presence of hydrogen to crystallize the high refractive index a-Si:H photonic crystal to form a nanocrystalline nc-Si:H photonic crystal having a lower refractive index than the high refractive index a-Si:H, and wherein the steps b) and c) are performed using the laser beam having a power above an amorphization laser power threshold, including selectively etching the refractive index pattern using a hydrogen (H) plasma to form an air pattern on the surface or in the bulk of the photonic crystal.

22. The method according to claim 6 wherein the step of stabilizing the colloidal crystal include growing a continuous layer of SiO₂ from a room temperature acid catalyzed reaction of gas phase SiCl₄ (Aldrich 99%) with condensed water on the sphere surface.

23. The method according to claim 6 or 22 wherein the monodispersed silica microspheres have a diameter in a range from about 0.1 to 3 about microns.

24. The method according to claim 6, 22 or 23 wherein the substrate has spatial confines of pre-selected shape and size in the surface thereof in which the silica microspheres deposit.

25. The method according to claim 22, 23 or 24 wherein the step of infiltrating the colloidal crystal with a silicon containing fluid and depositing silicon on the silica microspheres includes infiltrating with Si₂H₆, and depositing silicon using chemical vapor deposition (CVD).

26. The method according to claim 6 wherein the step of illuminating a selected region of the photonic crystal with a laser beam of effective wavelength and intensity for an effective period of time includes illuminating the photonic crystal using the 514 nm wavelength line of an Ar⁺ laser attached to a focusing optics array to give a pre-selected laser spot size on the photonic crystal.

27. The method according to claim 6 wherein the step of illuminating a selected region of the photonic crystal with a laser beam of effective wavelength and intensity for an effective period of time includes illuminating the photonic crystal using the 248 nm wavelength line of an excimer KrF laser attached to a focusing optics array to give a pre-selected laser spot size on the photonic crystal.

28. The method according to claim 1 wherein the selected material is an organic material so that the photonic crystal is synthesized from a polymeric material.

29. The method according to claim 28 wherein the phase change is a crystalline to glass transition or vice versa.

30. The method according to claim 1 The method according to claim 1 or 2 wherein the selected material is selected from the group consisting of organic materials, inorganic materials and mixtures thereof.

31. The method according to claim 1 wherein the pre-selected regions of the photonic crystal are chosen to give a phase change in the structure of the selected regions corresponding to any one of points, lines and bends having a micron scale.

32. The method according to claim 1 wherein the pre-selected regions of the photonic crystal are chosen to give a phase change in the structure of the selected regions corresponding to any one of junctions, gradients, superlattice and modulated structures, on a length scale larger than microns.

33. The method according to claim 2 wherein the effective wavelength and intensity of the laser beam are selected so that light is absorbed predominantly in a surface region of the photonic crystal.

34. The method according to claim 2 wherein the effective wavelength and intensity of the laser beam are selected so that light is absorbed in a volume below the surface region of the photonic crystal.

35. The method according to claim 2 wherein the step of illuminating a selected region of the photonic crystal with a laser beam includes illuminating the selected region with a continuous wave (CW) laser beam.

36. The method according to claim 2 wherein the step of illuminating a selected region of the photonic crystal with a laser beam includes illuminating the selected region with a pulsed laser beam.

37. The method according to claim 2 wherein the step of illuminating a selected region of the photonic crystal with a laser beam includes illuminating the selected region with a confocal laser system configured for two-photon or multi-photon absorption by the photonic crystal.

38. A photonic crystal, comprising:
a) a photonic crystal of a selected material; and
b) a pattern of phase changes in the structure of selected regions of the photonic crystal thereby changing a refractive index of the selected regions to produce a pattern of refractive index contrast in the photonic crystal.

39. The photonic crystal according to claim 38 wherein the selected material is an inorganic material.

40. The photonic crystal according to claim 39 wherein the inorganic material is selected from the group consisting of silicon, germanium, selenium, tellurium, tellurium binary and ternary alloys, zinc and cadmium chalcogenides, arsenic and antimony chalcogenides, germanium chalcogenides, tin chalcogenides and lead chalcogenides.

41. The photonic crystal according to claim 39 wherein the selected inorganic material is silicon so that the photonic crystal is a silicon photonic crystal.

42. The photonic crystal according to claim 38 wherein the selected material is an organic material so that the photonic crystal is synthesized from a polymeric material.

43. The photonic crystal according to claim 42 wherein the phase changes are crystalline to glass transitions or vice versa.

44. The photonic crystal according to claim 38 wherein the pre-selected regions of the photonic crystal are chosen to give a pattern of phase changes in the structure of the selected regions corresponding to any one of points, lines and bends having a micron scale.

45. The photonic crystal according to claim 38 wherein the pre-selected regions of the photonic crystal are chosen to give a pattern of phase changes in the structure of the selected regions corresponding to any one of junctions, gradients, superlattice and modulated structures, on a length scale larger than microns.

46. The photonic crystal according to claim 38 wherein the selected regions of the photonic crystal are predominantly in a surface region of the photonic crystal.

47. The photonic crystal according to claim 38 wherein the selected regions of the photonic crystal are predominantly in a volume below the surface region of the photonic crystal.
